(19) United States
(12) Patent Application Publication
(10) Pub. No.: US 2006/0144697 A1
(43) Pub. Date: Jul. 6, 2006

(54) Method of making coated article by sputtering cast target to form zinc oxide inclusive layer(s)

(75) Inventor: Sebastian Bobrowski, Jaworzno (PL)

Correspondence Address: NIXON & VANDERHYE, PC, 901 NORTH GLEBE ROAD, 11TH FLOOR, ARLINGTON, VA, 22203, US

(73) Assignee: Centre Luxembourgeois de Recherches pour le Verre et la Ceramique S.A. (C.R.V.C.) Dudelange, Grand Duchy (LU)

(21) Appl. No.: 11/029,655

(22) Filed: Jan. 6, 2005

(51) Int. Cl. C23C 14/32; C23C 14/00

(52) U.S. Cl. 204/192.15; 204/192.1

(57) ABSTRACT

A coated article includes a coating which has a zinc oxide inclusive layer provided as a contact layer under and directly contacting an infrared (IR) reflecting layer of a material such as silver. It has been found that the emissivity (or emittance) of the coated article can be reduced by sputtering a cast target(s) to form the zinc oxide inclusive contact layer—as opposed to sputtering a target formed by plasma spraying or the like. Thus, it has unexpectedly been found that the emissivity and/or resistivity of an IR reflecting layer can be improved (i.e., lowered) by using a cast target to sputter-form the contact layer located immediately under the IR reflecting layer.

This invention relates to a method of making a coated article including a layer comprising zinc oxide under an infrared (IR) reflecting layer. In certain example embodiments, layer comprising zinc oxide may be formed by sputtering a cast target comprising zinc and optionally other material(s) such as aluminum. Surprisingly, it has been found that the use of a cast target in sputtering the zinc oxide inclusive layer (as opposed to a target formed by plasma spraying or the like) permits a coated article with a lower emissivity and thus a lower sheet resistance (Rₛ) to be made.

### BACKGROUND OF THE INVENTION

Coated articles are known in the art for use in window applications such as insulating glass (IG) window units, vehicle windows, monolithic windows, and/or the like. It is known that in certain instances, it is desirable to heat treat (e.g., thermally temper, heat bend and/or heat strengthen) such coated articles for purposes of tempering, bending, or the like.

In certain example instances, designers of coated articles often strive for a combination of high visible transmission, substantially neutral color, low emissivity (or emittance), and low sheet resistance (Rₛ). High visible transmission and substantially neutral color may permit coated articles to be used in applications where these characteristics are desired such as in architectural or vehicle window applications, whereas low-emissivity (low-E) and low sheet resistance characteristics permit such coated articles to block significant amounts of IR radiation so as to reduce for example undesirable heating of vehicle or building interiors. In certain example instances, low U-values are also desired.

It is known to use a layer comprising zinc oxide as a contact layer under and contacting an IR reflecting layer of silver or the like, in a coated article. For example, see U.S. 2004/0121165, 2004/0005467, and 2003/0150711, the disclosures of which are all hereby incorporated herein by reference. Each of these references discloses the use of a zinc oxide inclusive contact layer under a silver based IR reflecting layer.

It will be appreciated that low emissivity values and low sheet resistance values are desirable. The general rule is that the lower the emissivity (or emittance), and thus the lower the sheet resistance, the better the IR blocking functionality of the coating. In other words, the lower the emissivity (or emittance) of the coating, the more IR radiation which can be blocked by the coating.

In view of the above, it will be apparent to those skilled in the art that there exists a need for coated articles which have low emissivity (or low emittance) and/or low sheet resistance values. It is a purpose of certain example embodiments of this invention to provide a method which can reduce the emissivity and/or sheet resistance of a coated article.

### BRIEF SUMMARY OF EXAMPLE EMBODIMENTS OF THE INVENTION

In certain example embodiments of this invention, a layer comprising zinc oxide is provided as a contact layer under and directly contacting an infrared (IR) reflecting layer of a material such as silver. Surprisingly, it has been found that the emissivity (or emittance) of the coated article can be reduced by sputtering a cast target(s) to form the contact layer comprising zinc oxide—as opposed to sputtering a target formed by plasma spraying or the like. Thus, it has unexpectedly been found that the emissivity and/or resistivity of an IR reflecting layer can be improved (i.e., lowered) by using a cast target to sputter-form the contact layer located immediately under the IR reflecting layer.

In certain example embodiments of this invention, this layer stack portion may be used in the context of a single silver layer stack, although this invention is not so limited. For instance, the instant invention is also applicable to low-E coatings including multiple silver based IR reflecting layers (e.g., double silver stacks).

In certain example embodiments, there is provided a method of making a coated article including a coating supported by a glass substrate, the method comprising: forming a dielectric layer on the glass substrate; forming a layer comprising zinc oxide on the glass substrate over at least the dielectric layer by sputtering at least one cast target comprising zinc; forming an infrared (IR) reflecting layer comprising silver on the glass substrate over and contacting the layer comprising zinc oxide; and forming another dielectric layer on the glass substrate over at least the IR reflecting layer.

In other example embodiments of this invention, there is provided a method of making a coated article including a coating supported by a glass substrate, the method comprising: forming a contact layer on the glass substrate by sputtering at least one cast target; forming an infrared (IR) reflecting layer on the glass substrate over and contacting the contact layer formed using the at least one cast target; and forming a dielectric layer on the glass substrate over at least the IR reflecting layer.

### BRIEF DESCRIPTION OF THE DRAWINGS

FIG. 1 is a cross sectional view of a coated article according to an example embodiment of this invention.

FIG. 2 is a graph comparing emissivity results using a cast target according to certain examples of this invention, versus a plasma sprayed target for comparative purposes, in sputtering a layer comprising zinc oxide onto a substrate so as to be located directly under and contacting an IR reflecting layer.

### DETAILED DESCRIPTION OF EXAMPLES OF THE INVENTION

Coated articles herein may be used in applications such as monolithic windows, IG window units, vehicle windows, and/or any other suitable application that includes single or multiple glass substrates.

Coated articles according to certain example embodiments of this invention typically include a coating that is supported by a substrate such as a glass substrate. The coating may include one or more IR reflecting layers of a material such as silver or the like. In certain example embodiments of this invention, a layer(s) comprising zinc oxide is provided as a contact layer under and directly contacting an IR reflecting layer(s). Surprisingly, it has been found that the emissivity (or emittance) of the coated article can be reduced by sputtering a cast target(s) to form the contact layer of or including zinc oxide—as opposed to sputtering a target formed by plasma spraying or the like. Thus, it has unexpectedly been found that the emissivity and/or resistivity of an IR reflecting layer can be improved (i.e., lowered) by using a cast target to sputter-form the contact layer located immediately under the IR reflecting layer.

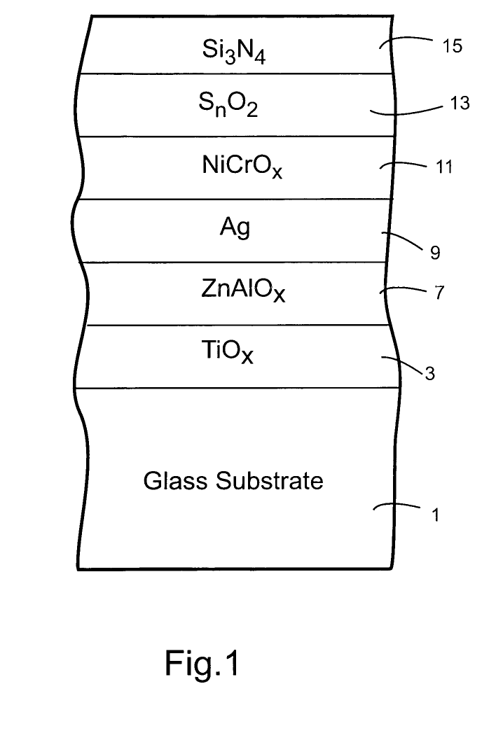

FIG. 1 is a cross sectional view of an example coated article. It is noted that this figure is provided for purposes of example only, and the example materials shown therein and the number of layers therein and their respective positions are not intended to be limiting. In certain example embodiments of this invention, this layer stack portion may be used in the context of a single silver layer stack, although this invention is not so limited.

FIG. 1 is a cross sectional view of a coated article (heat treated, or non-heat treated) according to an example embodiment of this invention. The coated article includes glass substrate 1 (e.g., clear, green, bronze, or blue-green glass substrate from about 1.0 to 10.0 mm thick, more preferably from about 1.0 mm to 6.0 mm thick), and a multi-layer coating (or layer system) provided on the substrate either directly or indirectly. As shown in FIG. 1, the coating comprises dielectric layer 3, zinc oxide inclusive layer 7, IR reflecting layer 9 including or of silver, gold, or the like, upper contact layer 11 of or including an oxide of nickel chrome (e.g., NiCrOₓ), metal oxide inclusive dielectric layer 13, and dielectric layer 15 of or including a material such as silicon nitride which may in certain example instances be a protective overcoat. Other layers and/or materials may also be provided in certain example embodiments of this invention, and it is also possible that certain layers may be removed or split in certain example instances.

In certain example embodiments, each of the layers 3, 7, 9, 11, 13 and 15 shown in FIG. 1 may be formed by sputtering a at least one target (e.g., planar target and/or CMAG target). For instances, titanium oxide layer 3 may be formed by sputtering one or more Ti inclusive targets in an atmosphere of argon and/or oxygen gas. As another example, the silver based IR reflecting layer may be formed by sputtering a planar silver target(s) in an atmosphere of argon gas. As yet another example, the silicon nitride layer 15 may be formed by sputtering a target of SiAl in an atmosphere including argon and nitrogen gas. However, in alternative embodiments, one or more of the layers may be formed in a different manner.

In monolithic instances, the coated article includes only one glass substrate 1 as illustrated in FIG. 1. However, monolithic coated articles herein may be used in devices such as IG window units for example. Typically, an IG window unit may include two spaced apart substrates. Example IG window units are illustrated and described, for example, in U.S. 2003/0150711, the disclosure of which is hereby incorporated herein by reference. An example IG window unit may include, for example, the coated glass substrate 1 shown in FIG. 1 coupled to another glass substrate via spacer(s), sealant(s) or the like with a gap being defined therebetween. This gap between the substrates in IG unit embodiments may in certain instances be filled with a gas such as argon (Ar). An example IG unit may comprise a pair of spaced apart clear glass substrates each about 4 mm thick one of which is coated with a coating herein in certain example instances, where the gap between the substrates may be from about 5 to 30 mm, more preferably from about 10 to 20 mm, and most preferably about 16 mm. In certain example instances, the coating may be provided on the side of the inner glass substrate 1 facing the gap.

In certain example IG unit embodiments of this invention, the coating is designed such that the resulting IG unit (e.g., with, for reference purposes, a pair of 4 mm clear glass substrates spaced apart by 16 mm with Ar gas in the gap) has a U-value of no greater than 1.25 W/(m 2K), more preferably no greater than 1.20 W/(m²K), even more preferably no greater than 1.15 W/(m²K), and most preferably no greater than 1.10 W/(m²K).

The bottom dielectric layer 3 may be of or include titanium oxide in certain example embodiments of this invention. The titanium oxide of layer 3 may in certain example instances be represented by TiOₓ, where x is from 1.5 to 2.5, most preferably about 2.0. The titanium oxide may be deposited via sputtering or the like in different embodiments. In certain example instances, dielectric layer 3 may have an index of refraction (n), at 550 nm, of at least 2.0, more preferably of at least 2.1, and possibly from about 2.3 to 2.6 when the layer is of titanium oxide. In certain embodiments of this invention, the thickness of titanium oxide inclusive layer 3 is controlled so as to allow a* and/or b* color values (e.g., transmissive, film side reflective, and/or glass side reflective) to be fairly neutral (i.e., close to zero) and/or desirable. Other materials may be used in addition to or instead of titanium oxide in certain example instances.

Lower contact layer 7, located directly under and contacting IR reflecting layer 9, in certain example embodiments of this invention is of or includes zinc oxide (e.g., ZnO). The zinc oxide of layer 7 may contain other materials as well such as Al (e.g., to form ZnAlOₓ) and/or stainless steel. For example, in certain example embodiments of this invention, zinc oxide layer 7 may be doped with from about 1 to 10% Al, more preferably from about 1 to 5% Al, and most preferably about 2 to 4% Al. The use of zinc oxide under the silver 9 allows for a good quality of silver to be achieved.

Infrared (IR) reflecting layer 9 is preferably substantially or entirely metallic and/or conductive, and may comprise or consist essentially of silver (Ag), gold, or any other suitable IR reflecting material. IR reflecting layer 9 help allow the coating to have low-E and/or good solar control characteristics. The IR reflecting layer may, however, be slightly oxidized in certain embodiments of this invention.

The upper contact layer 11 may be of or include nickel (Ni) oxide, chromium/chrome (Cr) oxide, or a nickel alloy oxide such as nickel chrome oxide (NiCrOₓ), or other suitable material(s), in certain example embodiments of this invention. The use of, for example, NiCrOₓ in this layer 11 allows durability to be improved. The NiCrOₓ layer 11 may be fully oxidized in certain embodiments of this invention (i.e., fully stoichiometric), or alternatively may only be partially oxidized. In certain instances, the NiCrOₓ layer 11 may be at least about 50% oxidized. Contact layer 11 (e.g., of or including an oxide of Ni and/or Cr) may or may not be oxidation graded in different embodiments of this invention. Oxidation grading means that the degree of oxidation in the layer changes throughout the thickness of the layer so that for example a contact layer may be graded so as to be less oxidized at the contact interface with the immediately adjacent IR reflecting layer than at a portion of the contact layer(s) further or more/most distant from the immediately adjacent IR reflecting layer. Descriptions of various types of oxidation graded contact layers are set forth in U.S. Pat. No. 6,686,050, the disclosure of which is hereby incorporated herein by reference. Contact layer 11 (e.g., of or including an oxide of Ni and/or Cr) may or may not be continuous in different embodiments of this invention across the entire IR reflecting layer 9.

Dielectric layer 13 may be of or include a metal oxide such as tin oxide (e.g., SnO₂) in certain example embodiments of this invention. Other materials such as other metal oxides may instead be used in layer 13 in alternative embodiments. Dielectric layer 15, which may be an overcoat in certain example instances, may be of or include silicon nitride (e.g., Si₃N₄) or any other suitable material in certain example embodiments of this invention. Optionally, other layers may be provided above layer 15. Layer 15 is provided for durability purposes, and to protect the underlying layers during heat treatment and/or environmental use. In certain example embodiments, layer 15 may have an index of refraction (n) of from about 1.9 to 2.2, more preferably from about 1.95 to 2.05, as may layer 13.

Other layer(s) below or above the illustrated coating may also be provided. Thus, while the layer system or coating is “on” or “supported by” substrate 1 (directly or indirectly), other layer(s) may be provided therebetween. Thus, for example, the coating of FIG. 1 may be considered “on” and “supported by” the substrate 1 even if other layer(s) are provided between layer 3 and substrate 1. Moreover, certain layers of the illustrated coating may be removed in certain embodiments, while others (not shown) may be added between the various layers or the various layer(s) may be split with other layer(s) added between the split sections in other embodiments of this invention without departing from the overall spirit of certain embodiments of this invention.

As mentioned above, it has unexpectedly been found that the emissivity (or emittance) of the coated article can be reduced by sputtering a cast target(s) to form the contact layer 7 of or including zinc oxide—as opposed to sputtering a target formed by plasma spraying or the like. Thus, it has unexpectedly been found that the emissivity and/or resistivity of an IR reflecting layer 9 can be improved (i.e., lowered) by using a cast target to sputter-form the contact layer 7 located immediately under the IR reflecting layer 9. The cast target used to form lower contact layer 7 may be of pure Zn in certain example embodiments, but is more preferably of Zn that is doped with another material such as Al (e.g., from 1-10%, more preferably from 1-5% Al).

In certain example embodiments of this invention, the use of a cast target(s) (compared to a target formed by plasma spraying) to form contact layer 7 causes the coating to realize a normal emissivity which is at least about 2% lower, more preferably at least about 3% lower, and sometimes at least about 4% lower.

One example technique for forming a “cast” sputtering target is where the metal or metals of which the target is to be made is/are melted and poured into a mold or the like so as to cast the target. Another example for making a cast target is where a target tube is produced from metal by casting a solid bar, and forging the bar into a cylindrical billet and subsequently producing a tube or other suitable shape by machining. Continuous casting techniques, and/or centrifugal casting techniques, may also be used in forming cast targets. A cast target may be cast into any suitable shape, including but not limited to a cylindrical tube target, a planar target, or the like. In certain example cylindrical tube cast targets, the material to be sputtered may be cast as an outer layer onto another inner supporting layer which may or may not be cast. Example techniques for forming cast targets are discussed in U.S. Pat. No. 6,793,784, U.S. Pat. No. 6,719,034, DE 2427098, DE 3532131 Al, DE 4,216870, the disclosures of which are hereby incorporated herein by reference. Generally, such cast targets have at least a portion thereof formed by molding of a molten or semi-molten material (preferably at least a portion including material to be sputtered).

In certain example embodiments, a cast target supplied by Heraus may be used to sputter-deposit the zinc oxide layer 7. This cast target has been found to improve the process stability which in turn reduces production losses caused by sudden power jumps (arcs). It has also been found as mentioned above that the use of this cast ZnAl target leads to a final product with lower resistivity (e.g., see Examples below).

While various thicknesses may be used in different embodiments of this invention, example thicknesses and materials for the respective layers on the glass substrate 1 in the FIG. 1 embodiment are as follows, from the glass substrate outwardly:

TABLE 1
(Example Materials/Thicknesses; FIG. 1 Embodiment)

| | Preferred | More | |
|---|---|---|---|
| Layer | Range (\acute{Å}) | Preferred (\acute{Å}) | Example (Å) |
| TiOₓ (layer 3) | 30-400 \acute{Å} | 100-150 \acute{Å} | 128 Å |
| ZnAlOₓ (layer 7) | 10-300 \acute{Å} | 60-100 \acute{Å} | 67 Å |
| Ag (layer 9) | 50-250 \acute{Å} | 80-150 \acute{Å} | 120 Å |
| NiCrOₓ (layer 11) | 10-80 \acute{Å} | 20-70 \acute{Å} | 45 Å |
| SnO₂ (layer 13) | 40-400 Å | 100-150 Å | 129 Å |
| Si₃N₄ (layer 15) | 50-750 \acute{Å} | 250-350 \acute{Å} | 294 Å |

In certain example embodiments of this invention, coated articles herein may have the following low-E (low emissivity) and/or solar characteristics set forth in Table 2 when measured monolithically before any possible HT.

TABLE 2
Low-E/Solar Characteristics (Monolithic; pre-HT)

| Characteristic | General | More Preferred | Most Preferred |
|---|---|---|---|
| Rₛ (ohms/sq.): | <=6.0 | <=5.0 | <=4.0 |
| Avg. resistivity (H/cm²) | <=4.5 | <=4.35 | <=4.20 |
| Eₙ: | <=0.050 | <=0.044 | <=0.043 |
| Tᵥᵢₛ (%): | >=60 | >=70 | >=78 |

Moreover, coated articles including coatings according to certain example embodiments of this invention have the following optical characteristics when used in the context of an IG window unit. For purposes of reference only and without limitation, data may be in the context of an IG window unit with a pair of 4 mm thick clear glass substrates spaced 16 mm apart via a gap filled with Ar gas. It is noted that U-value is measured in the context of an IG Unit, as is Tᵥᵢₛ-IG.

TABLE 3
Example Optical Characteristics (IG Unit)

| Characteristic | General | More Preferred |
|---|---|---|
| Tᵥᵢₛ-IG: | >=70% | >=78% |
| U-value (IG)(W/(m²K)): | <=1.25 | <=1.15 (or <=1.10) |

### EXAMPLES

The following examples are provided for purposes of example only, and are not intended to be limiting. All examples were made so as to have the layer stack shown in FIG. 1, and are for purposes of example only. The only difference between the first set of examples and the second set (or Comparative Set) of examples was the type of target used to sputter the zinc oxide inclusive contact layer 7 under the silver IR reflecting layer 9.

In the first set of examples, ten coated articles were formed using a cast target of ZnAl (Zn doped with about 2-4% Al) to sputter-deposit the ZnAlOₓ contact layer 7. However, in the second set (or Comparative Set) of examples where six coated articles were formed, the ZnAl target (Zn doped with about 2-4% Al) used to sputter-deposit the ZnAlOₓ contact layer 7 was formed by a plasma-spraying technique. Otherwise, the examples were the same.

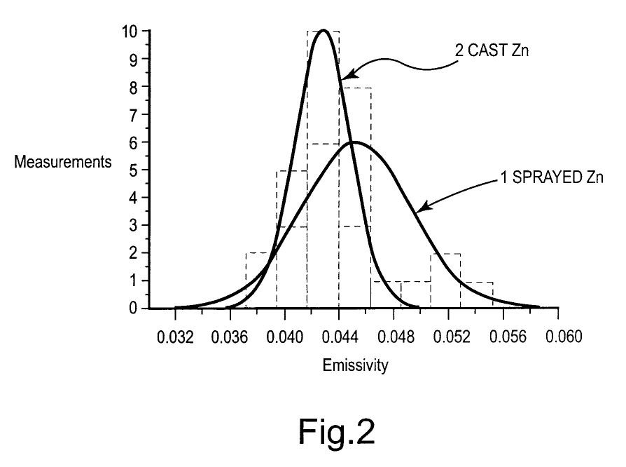

FIG. 2 is a graph illustrating the results of these examples. In particular, it can be seen that the coatings in which the ZnAlOₓ contact layer 7 was sputter-deposited using a cast target (i.e., the CAST Zn in FIG. 2) realized a significantly lower normal emissivity (and thus a lower sheet resistance) compared to the second set (or Comparative Set) of examples where the ZnAlOₓ contact layer 7 was sputter-deposited using a target formed by plasma-spraying (SPRAYED Zn in FIG. 2). The unexpected advantages associated with the use of the cast target(s) in forming layer 7 are clear. In particular, the use of the cast target (compared to the plasma-sprayed target) resulted in the average normal emissivity dropping from about 0.045 to about 0.042 or 0.043 as shown in FIG. 2. Moreover, the average resistivity measured over the number of samples dropped from 4.4 to 4.2 H/cm , which is also highly advantageous.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making a coated article including a coating supported by a glass substrate, the method comprising:
forming a dielectric layer on the glass substrate;
forming a layer comprising zinc oxide on the glass substrate over at least the dielectric layer by sputtering at least one cast target comprising zinc;
forming an infrared (IR) reflecting layer comprising silver on the glass substrate over and contacting the layer comprising zinc oxide; and
forming another dielectric layer on the glass substrate over at least the IR reflecting layer.

2. The method of claim 1, wherein the cast target is composed of zinc doped with from about 1-10% aluminum.

3. The method of claim 1, wherein the dielectric layer and the another dielectric layer are formed by sputtering targets formed by plasma spraying.

4. The method of claim 1, wherein the coating has a normal emissivity of less than or equal to 0.044.

5. The method of claim 1, wherein the coating has a normal emissivity of less than or equal to 0.043.

6. The method of claim 1, wherein the coating has an average resistivity of less than or equal to 4.35 H/cm².

7. The method of claim 1, wherein the coating has an average resistivity of less than or equal to 4.20 H/cm².

8. The method of claim 1, wherein the coated article has a visible transmission of at least about 60%.

9. The method of claim 1, wherein the dielectric layer comprises an oxide of titanium, and is in direct contact with the glass substrate.

10. The method of claim 1, further comprising forming a contact layer comprising an oxide of Ni and/or Cr on the glass substrate over and contacting the IR reflecting layer.

11. The method of claim 10, further comprising forming a layer comprising a metal oxide on the glass substrate over and contacting the contact layer comprising an oxide of Ni and/or Cr.

12. The method of claim 1, wherein the use of the cast target(s) to form the layer comprising zinc oxide causes the coating to realize a normal emissivity which is at least about 2% lower compared to if a target(s) formed by plasma spraying was used to form the layer comprising zinc oxide.

13. The method of claim 1, wherein the use of the cast target(s) to form the layer comprising zinc oxide causes the coating to realize a normal emissivity which is at least about 3% lower compared to if a target(s) formed by plasma spraying was used to form the layer comprising zinc oxide.

14. The method of claim 1, wherein the coated article is heat treated.

15. The method of claim 1, wherein the coating includes only one IR reflecting layer comprising silver.

16. The method of claim 1, wherein said another dielectric layer comprises silicon nitride.

17. The method of claim 1, further comprising coupling the glass substrate with the coating thereon to another substrate so as to form an IG window unit, wherein the IG window unit has a U-value of no greater than 1.25 W/(m²K).

18. The coated article of claim 1, further comprising coupling the glass substrate with the coating thereon to another substrate so as to form an IG window unit, wherein the IG window unit has a U-value of no greater than 1.15 W/(m²K).

19. A method of making a coated article including a coating supported by a glass substrate, the method comprising:
forming a contact layer on the glass substrate by sputtering at least one cast target;
forming an infrared (IR) reflecting layer on the glass substrate over and contacting the contact layer formed using the at least one cast target; and
forming a dielectric layer on the glass substrate over at least the IR reflecting layer.

20. The method of claim 19, wherein the cast target comprises zinc so that the contact layer comprises zinc oxide.

21. The method of claim 19, further comprising forming a layer comprising an oxide of titanium on the glass substrate so as to be located between the glass substrate and the contact layer.
